(19) United States
(12) Patent Application Publication
(10) Pub. No.: US 2026/0088111 A1
(43) Pub. Date: Mar. 26, 2026

(54) MEMORY DEVICE

(71) Applicant: SK hynix Inc., Icheon-si (KR)

(72) Inventor: Nam Cheol JEON, Icheon-si (KR)

(21) Appl. No.: 19/005,599

(22) Filed: Dec. 30, 2024

(30) Foreign Application Priority Data
Sep. 23, 2024 (KR) 10-2024-0128100

(51) Int. Cl. G11C 16/34; G11C 16/04; G11C 16/08; G11C 16/30

(52) U.S. Cl. CPC G11C 16/3459; G11C 16/0483; G11C 16/08; G11C 16/30

(57) ABSTRACT

A memory device includes a string, a voltage generation circuit, a decoder, and a control logic. The string includes at least one drain select transistor coupled to at least one drain select line. The voltage generation circuit generates at least one operating voltage. The decoder transfers the at least one operating voltage to at least one global drain select line, and couples the at least one global drain select line with the at least one drain select line. The control logic controls the voltage generation circuit to generate a negative voltage while an equalization operation is performed, and controls the decoder to transfer the negative voltage to the at least one global drain select line while coupling the at least one global drain select line with the at least one drain select line.

### CROSS-REFERENCES TO RELATED APPLICATION

The present application claims priority under 35 U.S.C. § 119(a) to Korean Patent Application No. 10-2024-0128100 filed on Sep. 23, 2024, which is incorporated herein by reference in its entirety.

### BACKGROUND

### 1. Technical Field

Various embodiments generally relate to a memory device.

### 2. Related Art

Memory devices are core components of electronic devices, serving a broad spectrum of modern applications, including computing, communications, artificial intelligence, and data storage. The memory devices may comprise elements such as transistors, diodes, integrated circuits (ICs), and other related components.

As technology advances, the memory devices are being developed to achieve greater speed and finer structures. However, the increasing circuit density introduces challenges, such as higher resistance in metal wiring and greater parasitic capacitance between insulating layers, which exacerbate RC delay. This increase in RC delay can degrade the performance of memory devices by slowing signal transmission and causing disturbs. To mitigate RC delay, materials with low metal resistance may be used for the gate of the transistor, or oxide materials with a low dielectric constant may be incorporated into the ON stack (Oxide/Nitride stack). However, these approaches may face significant challenges due to processing limitations.

### SUMMARY

In an embodiment, a memory device may include a string, a voltage generation circuit, a decoder, and a control logic. The string may include at least one drain select transistor coupled to at least one drain select line. The voltage generation circuit may generate at least one operating voltage. The decoder may transfer the at least one operating voltage to at least one global drain select line, and may couple the at least one global drain select line with the at least one drain select line. The control logic may control the voltage generation circuit to generate a negative voltage while an equalization operation is performed, and may control the decoder to transfer the negative voltage to the at least one global drain select line while coupling the at least one global drain select line with the at least one drain select line.

In an embodiment, a memory device may include a string, a voltage generation circuit, a decoder, and a control logic. The string may include at least one dummy memory cell coupled to at least one dummy word line. The voltage generation circuit may generate at least one operating voltage. The decoder may transfer the at least one operating voltage to at least one global dummy word line, and may couple the at least one global dummy word line with the at least one dummy word line. The control logic may control the voltage generation circuit to generate a negative voltage while an equalization operation is performed, and may control the decoder to transfer the negative voltage to the at least one global dummy word line while coupling the at least one global dummy word line with the at least one dummy word line.

In an embodiment, a memory device may include a string, a buffer circuit, and a control logic. The string may be coupled to a bit line and include a target memory cell. The buffer circuit may precharge the bit line based on a verification result for the target memory cell while a connection signal is enabled in a bit line setup operation. The control logic may enable the connection signal for a first duration when the bit line is included in a first bit line group, and may enable the connection signal for a second duration when the bit line is included in a second bit line group, in the bit line setup operation.

### BRIEF DESCRIPTION OF THE DRAWINGS

FIG. 1 is a block diagram illustrating a memory device according to an embodiment of the present disclosure.

FIG. 2 is a circuit diagram illustrating a memory block according to an embodiment of the present disclosure.

FIG. 3 is a block diagram illustrating a detailed configuration of a decoder of FIG. 1, according to an embodiment of the present disclosure.

FIG. 4 is a diagram illustrating program states of memory cells according to an embodiment of the present disclosure.

FIG. 5 is a timing diagram illustrating the execution of a read operation on a target memory cell, according to an embodiment of the present disclosure.

FIG. 6 is a diagram illustrating a situation in which a read disturb occurs during a period of a word line discharge operation in a read operation, according to an embodiment of the present disclosure.

FIG. 7 is a diagram illustrating an operation for mitigating the effects of a read disturb, according to an embodiment of the present disclosure.

FIG. 8 is a timing diagram illustrating the execution of a read operation on a target memory cell, according to an embodiment of the present disclosure.

FIG. 9 is a diagram illustrating an operation for mitigating the effects of a read disturb, according to an embodiment of the present disclosure.

FIG. 10 is a diagram illustrating an operation for mitigating the effects of a read disturb, according to an embodiment of the present disclosure.

FIG. 11 is a block diagram illustrating a buffer circuit according to an embodiment of the present disclosure.

FIG. 12 is a diagram illustrating a first bit line group and a second bit line group according to an embodiment of the present disclosure.

FIG. 13 is a timing diagram illustrating the execution of a bit line setup operation during a bit line setup time, according to an embodiment of the present disclosure.

### DETAILED DESCRIPTION

Hereinafter, embodiments of the present disclosure will be described in more detail with reference to the accompanying drawings.

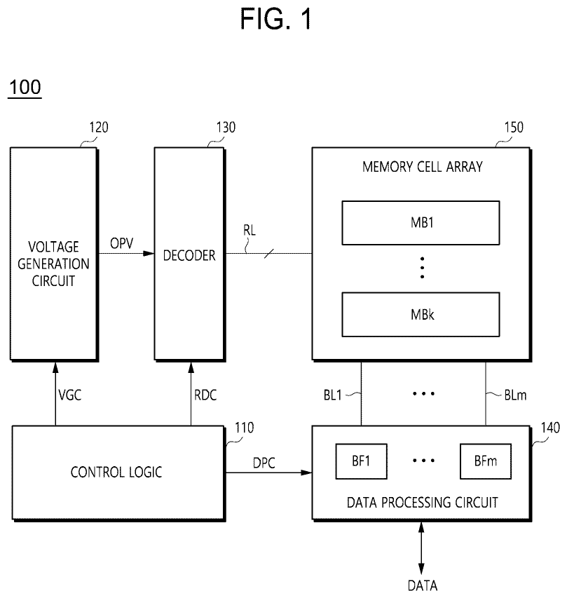

FIG. 1 is a block diagram illustrating a memory device 100 according to an embodiment of the present disclosure.

Referring to FIG. 1, the memory device 100 may store data DATA under the control of an external device (not shown) and output the stored data DATA to the external device. The memory device 100 may include a control logic 110, a voltage generation circuit 120, a decoder 130, a data processing circuit 140, and a memory cell array 150. Each of the control logic 110, the voltage generation circuit 120, the decoder 130, and the data processing circuit 140 may include hardware, software, firmware, or a combination thereof.

The control logic 110 may control the voltage generation circuit 120, the decoder 130, and the data processing circuit 140 to perform access operations, such as a program operation, a read operation, an erase operation, and the like, on the memory cell array 150 in response to commands from the external device. The control logic 110 may control the voltage generation circuit 120 using a voltage generation circuit control signal VGC, the decoder 130 using a decoder control signal RDC, and the data processing circuit 140 using a data processing circuit control signal DPC.

The voltage generation circuit 120 may generate one or more operating voltages OPV (e.g., program voltage, read voltage, verification voltage, etc.) and output the operating voltages OPV to the decoder 130.

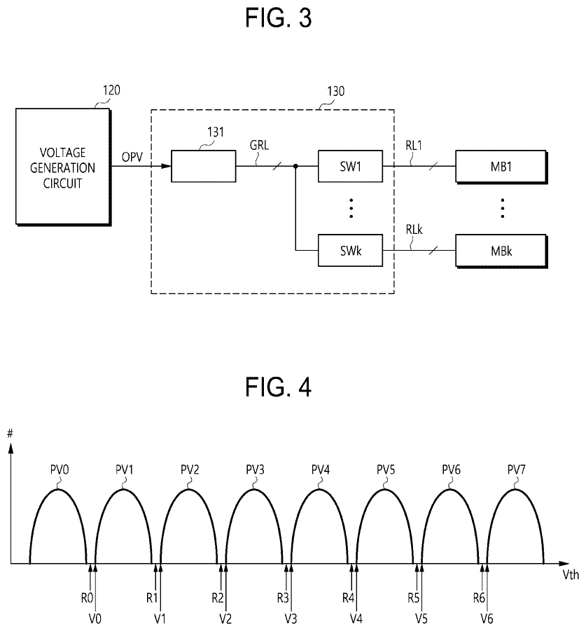

The decoder 130 may be coupled to memory blocks MB1 to MBk included in the memory cell array 150 through a plurality of row lines RL. The decoder 130 may select and access at least one of the memory blocks MB1 to MBk by controlling the row lines RL. The decoder 130 may transfer the operating voltages OPV output from the voltage generation circuit 120 to the row lines RL coupled to a selected memory block of the memory blocks MB1 to MBk. The configuration of the decoder 130 will be described in more detail with reference to FIG. 3.

The data processing circuit 140 may store data DATA read from or to be written to the memory cell array 150. The data processing circuit 140 may include buffer circuits BF1 to BFm, each coupled to corresponding bit lines BL1 to BLm. Each of the buffer circuits BF1 to BFm may store data DATA read from or to be written to memory cells through corresponding bit lines.

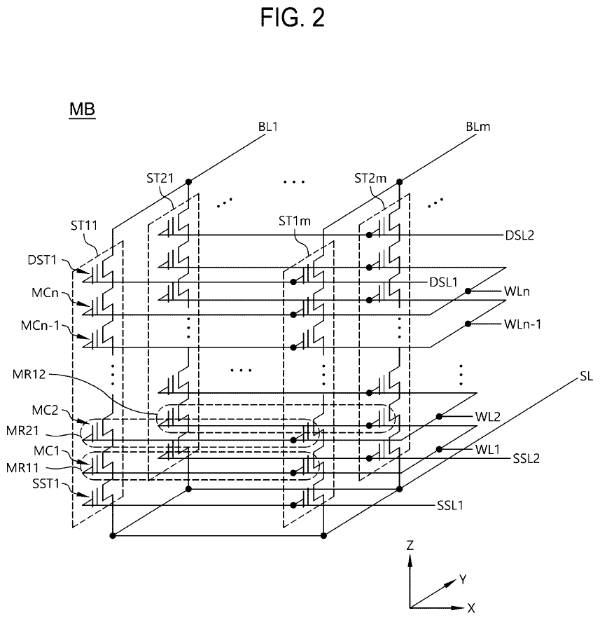

The memory cell array 150 may include the memory blocks MB1 to MBk. Each of the memory blocks MB1 to MBk may include a plurality of memory cells. The configuration of each of the memory blocks MB1 to MBk will be described with reference to FIG. 2.

FIG. 2 is a circuit diagram illustrating a memory block MB according to an embodiment of the present disclosure. Each of the memory blocks MB1 to MBk of FIG. 1 may be configured similarly to the memory block MB of FIG. 2.

Referring to FIG. 2, the memory blocks MB may be coupled to the decoder 130 through drain select lines DSL1 and DSL2, source select lines SSL1 and SSL2, and word lines WL1 to WLn. The drain select lines DSL1 and DSL2, the source select lines SSL1 and SSL2, and the word lines WL1 to WLn may be included in the row lines RL.

The memory block MB may include strings ST11 to ST1m and ST21 to ST2m. Each of the strings ST11 to ST1m and ST21 to ST2m may extend along a vertical direction (Z direction). Within the memory block MB, m strings may be arranged in a row direction (X direction). In FIG. 2, two strings are shown arranged in a column direction (Y direction), but this is for illustrative purposes only, and three or more strings may be arranged in the column direction (Y direction).

The strings ST11 to ST1m and ST21 to ST2m may be configured identically. For example, the string ST11 may include a source select transistor SST, memory cells MC1 to MCn, and a drain select transistor DST, coupled in series with each other between the source line SL and the bit line BL1. A source of the source select transistor SST may be coupled to the source line SL, and a drain of the drain select transistor DST may be coupled to the bit line BL1. The memory cells MC1 to MCn may be coupled in series with each other between the source select transistor SST and the drain select transistor DST. In an embodiment, a plurality of source select transistors may be coupled in series between the source line SL and the memory cell MC1. In an embodiment, a plurality of drain select transistors may be coupled in series between the bit line BL1 and the memory cell MCn.

Source select transistors at the same position in the vertical direction may be configured as shown below. Specifically, gates of the source select transistors of strings arranged in the same row may be coupled to the same source select line. For example, gates of the source select transistors of strings ST11 to ST1m in a first row may be coupled to a source select line SSL1. For example, gates of the source select transistors of a second row of strings ST21 to ST2m may be coupled to a source select line SSL2.

In an embodiment, source select transistors of two or more rows of strings may be coupled in common to a single source select line. For example, the source select transistors of the first and second rows of strings ST11 to ST1m and ST21 to ST2m may be coupled in common to one source select line, and the source select transistors of the third and fourth rows of strings may be coupled in common to one source select line.

Drain select transistors at the same position in a vertical direction may be configured as shown below. Specifically, the gates of the drain select transistors of strings arranged in the same row may be coupled to the same drain select line. For example, the gates of the drain select transistors of the strings ST11 to ST1m of the first row may be coupled to the drain select line DSL1. For example, the gates of the drain select transistors of the second row of the strings ST21 to ST2m may be coupled to the drain select line DSL2.

Strings arranged in the same column may be coupled to the same bit line. For example, strings ST11 and ST21 in a first column may be coupled to the bit line BL1. For example, strings ST1m and ST2m in an mth column may be coupled to the bit line BLm.

Gates of memory cells at the same position in the vertical direction may be coupled to the same word line. For example, in the strings ST11 to ST1m and ST21 to ST2m, memory cells that are at the same position in a direction perpendicular to the memory cell MC1 may be coupled to the word line WL1.

Among the memory cells, memory cells coupled to the same word line in the same row may constitute one memory region. For example, memory cells coupled to the word line WL1 in the first row may constitute one memory region MR11. For example, memory cells coupled to the word line WL1 in the second row may constitute one memory region MR12. For example, memory cells coupled to word line WL2 in the first row may constitute one memory region MR21. Depending on the number of rows, each word line may be coupled to multiple memory regions. The memory cells constituting one memory region may be accessed simultaneously.

In an embodiment, the memory block MB may be further coupled to at least one dummy word line other than the word lines WL1 to WLn. For example, at least one dummy word line may exist between each of the drain select lines DSL1 and DSL2 and the word line WLn. For example, there may be at least one dummy word line between each of the source select lines SSL1 and SSL2 and the word line WL1. The at least one dummy word line may be coupled to dummy memory cells in a manner similar to memory cells.

FIG. 3 is a block diagram illustrating a detailed configuration of the decoder 130 of FIG. 1, according to an embodiment of the present disclosure.

Referring to FIG. 3, the decoder 130 may include a voltage transfer circuit 131 and switch circuits SW1 to SWk. The voltage transfer circuit 131 and the switch circuits SW1 to SWk may be controlled by the decoder control signal RDC of FIG. 1.

The voltage transfer circuit 131 may receive the operating voltages OPV output from the voltage generation circuit 120 and transfer the operating voltages OPV to global row lines GRL. The global row lines GRL may include at least one global drain select line, at least one global dummy word line, at least one global source select line, and a plurality of global word lines. For example, the voltage transfer circuit 131 may transfer a read voltage output from the voltage generation circuit 120 to a global word line corresponding to a selected word line. For example, the voltage transfer circuit 131 may transfer a pass voltage output from the voltage generation circuit 120 to at least one global word line corresponding to at least one non-selected word line.

The switch circuits SW1 to SWk may selectively couple the row lines RL1 to RLk coupled to the memory blocks MB1 to MBk, respectively, with the global row lines GRL. When at least one of the switch circuits SW1 to SWk is enabled and remaining switch circuits are disabled, the operating voltages OPV may be transferred from the global row lines GRL to the row lines RL coupled to the enabled switch circuit. Thus, a memory block coupled to the enabled switch circuit may be selectively accessed. The row lines coupled to each of the memory blocks MB1 to MBk may include at least one drain select line, at least one dummy word line, at least one source select line, and a plurality of word lines. The row lines RL1 to RLk may be included in the row lines RL of FIG. 1.

Referring again to FIG. 1, the control logic 110 may control an equalization operation in a read operation. The equalization operation may be an operation to equalize a voltage level of a selected word line on which the read operation is performed and a voltage level of at least one non-selected word line. The control logic 110 may control the voltage generation circuit 120 and the decoder 130 to perform the equalization operation such that the voltage level of the selected word line and the voltage level of at least one non-selected word line are equalized while the equalization operation is performed. Specifically, the control logic 110 may control the voltage generation circuit 120 to generate the at least one operating voltage OPV for equalizing. And, the control logic 110 may control the decoder 130 to transfer the at least one operating voltage OPV output from the voltage generation circuit 120 to the global word lines GRL while coupling the global word lines GRL to the selected word line and the at least one non-selected word line.

Further, the control logic 110 may control the voltage generation circuit 120 to generate a negative voltage while the equalization operation is performed. Further, the control logic 110 may control the decoder 130 to transfer the negative voltage to at least one global drain select line while coupling the at least one global drain select line with the at least one drain select line.

Further, the control logic 110 may control the voltage generation circuit 120 and the decoder 130 such that at least one source select line is discharged while the equalization operation is performed. Specifically, in the equalization operation, the control logic 110 may control the decoder 130 to transfer a ground voltage output from the voltage generation circuit 120 to at least one global source select line during the coupling of at least one source select line with the at least one global source select line.

In an embodiment, the control logic 110 may control the voltage generation circuit 120 and the decoder 130 such that at least one dummy word line is discharged while the equalization operation is performed. Specifically, in the equalization operation, the control logic 110 may control the decoder 130 to transfer the negative voltage to at least one global dummy word line during the coupling of at least one dummy word line with the at least one global dummy word line.

The memory device may include NAND Flash Memory, three-dimensional NAND Flash Memory, NOR Flash memory, Resistive Random Access Memory (RRAM), Phase-Change Memory (PRAM), Magnetoresistive Random Access Memory (MRAM), Ferroelectric Random Access Memory (FRAM), or Spin Transfer Torque Random Access Memory (STT-RAM), among other types of memory.

FIG. 4 is a diagram illustrating program states PV0 to PV7 of memory cells according to an embodiment of the present disclosure. A horizontal axis Vth may denote a threshold voltage of a memory cell, and a vertical axis # may denote the number of memory cells having a corresponding threshold voltage.

Referring to FIG. 4, each memory cell may be in one of the program states PV0 to PV7, based on a data value of three-bit data stored therein. In an embodiment, when k-bit data is stored in each of the memory cells, the memory cells may exist in 2\hat{ }k program states.

In a program operation on target memory cells in an erased state, the decoder 130 may apply a program voltage to a selected word line coupled with the target memory cells. Threshold voltages of the target memory cells may rise in response to the program voltage.

To verify that the program states PV0 to PV7 are properly formed in the target memory cells, the decoder 130 may apply verification voltages V0 to V6, corresponding to the program states PV1 to PV7, to the selected word line. For example, to verify that a target memory cell coupled to the selected word line is in a program state PV1, the decoder 130 may apply a verification voltage V0 to the selected word line. If a target memory cell has a threshold voltage lower than the verification voltage V0, it may be turned on in response to the verification voltage V0, and thus the state of a bit line coupled to the target memory cell may change. If the target memory cell has a threshold voltage higher than the verification voltage V0, it may be turned off in response to the verification voltage V0, and thus the state of the bit line coupled to the target memory cell may remain unchanged. A buffer circuit coupled to the bit line may sense the state of the bit line and store a verification result indicating whether a program operation has been completed for the target memory cell.

Specifically, if a target memory cell, which should be in a program state PV1, is turned on in response to the verification voltage V0, it may be determined that the program operation for the target memory cell is incomplete. Accordingly, the program operation may proceed further to increase the threshold voltage of the target memory cell. Specifically, as the bit line coupled to the target memory cell is precharged to a program-allow voltage level (e.g., a ground voltage level), the threshold voltage of the target memory cell may be increased in response to an additional program voltage.

However, if the target memory cell that is to be in the program state PV1 is turned off in response to the verification voltage V0, the program operation for the target memory cell may be determined to be complete. Accordingly, the program operation may proceed such that the threshold voltage of the target memory cell is no longer elevated. Specifically, as the bit line coupled to the target memory cell is precharged to a program-inhibit voltage level, the threshold voltage of the target memory cell may remain unchanged even when an additional program voltage is applied.

If the number of target memory cells with threshold voltages lower than the verification voltage V0 among the target memory cells that should be in the program state PV1 is less than a predetermined number, it may be determined that a program operation is complete for the program state PV1. In a similar manner, the completion of program operation for the program states PV2 to PV7 may be determined using verification voltages V1 to V6. As used herein, the term “predetermined” with respect to a parameter, such as timing, time, or voltage level, refers to a value established prior to the parameter's use in a process or algorithm. In some embodiments, the parameter's value is determined before the process or algorithm begins. In other embodiments, the value is determined during the process or algorithm but before the parameter is used in the process or algorithm.

A read operation for target memory cells in the program states PV0 to PV7 may be performed using read voltages R0 to R6, which are positioned between the program states PV0 to PV7. Specifically, when each of the read voltages R0 to R6 is applied to a target memory cell, it can be determined whether a threshold voltage of the target memory cell is higher or lower than each of the read voltage R0 to R6. As a result, a program state of the target memory cell can be identified among the program states PV0 to PV7, allowing data stored in the target memory cell to be output.

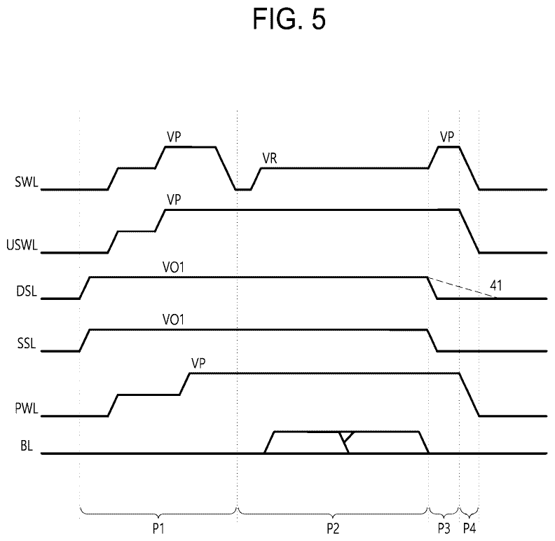

FIG. 5 is a timing diagram illustrating the execution of a read operation on a target memory cell, according to an embodiment of the present disclosure.

Referring to FIG. 5, a selected word line SWL may be a word line coupled with the target memory cell for which the read operation is to be performed. A non-selected word line USWL may refer to one or more word lines, coupled with a string including the target memory cell, which are not designated as the selected word line SWL. Hereinafter, the string may be referred to as a selected string. A drain select line DSL may refer to one or more drain select lines DSL coupled with the selected string. A source select line SSL may refer to one or more source select lines SSL coupled with the selected string. A dummy word line PWL may refer to one or more dummy word lines PWL coupled between word lines coupled to the selected string and the drain select lines DSL and/or between the word lines coupled to the selected string and the source select lines SSL. The selected string may be coupled to a selected bit line BL.

In periods P1 to P4, the voltage generation circuit 120 may output operating voltages OPV required for the read operation. The decoder 130 may couple the drain select lines DSL, the source select lines SSL, the selected word line SWL, the non-selected word lines USWL, and the dummy word lines PWL with corresponding global row lines in the periods P1 to P4, respectively, and may transfer the operating voltages OPV output from the voltage generation circuit 120 to the global row lines.

In the period P1, predetermined voltages may be applied to the drain select lines DSL, the source select lines SSL, the selected word line SWL, the non-selected word lines USWL, and the dummy word lines PWL at predetermined timings. Specifically, a turn-on voltage V01 may be applied to the drain select lines DSL and the source select lines SSL to turn on drain select transistors coupled to the drain select lines DSL and source select transistors coupled to the source select lines SSL in the selected string. In addition, a pass voltage VP to turn on memory cells coupled to the selected word line SWL and the non-selected word lines USWL in the selected string and dummy memory cells coupled to the dummy word lines PWL may be applied to the selected word line SWL, the non-selected word lines USWL, and the dummy word lines PWL. The pass voltage VP may be higher than a read voltage VR. As a result, the channel of the selected string may be initialized, i.e., it may be discharged to a source line SL.

In the period P2, the read voltage VR may be applied to the selected word line SWL, the state of the bit line BL may be changed in response to the read voltage VR, and data may be read from the target memory cell by sensing the state of the bit line BL.

In the period P3, an equalization operation may be performed. Specifically, the drain select lines DSL and the source select lines SSL may be discharged. Accordingly, in the selected string, the drain select transistors coupled to the drain select lines DSL and the source select transistors coupled to the source select lines SSL may be turned off. As a result, the channel of the selected string may float, isolated from both the bit line BL and the source line SL.

Then, the selected word line SWL, the non-selected word lines USWL, and the dummy word lines PWL may be equalized. For example, the equalization operation may be performed by raising a voltage level of the selected word line SWL to a level at or near the pass voltage VP applied to the non-selected word lines USWL. As another example, the equalization may proceed by increasing the voltage level of the selected word line SWL to a level intermediate between the read voltage VR and the pass voltage VP, while decreasing voltage levels of the non-selected word lines USWL and the dummy word lines PWL. The equalization operation may be performed to prevent hot carrier injection (HCI) disturb from being induced into the selected word line SWL, if the selected word line SWL, with a lower voltage level, is discharged before the non-selected word lines USWL, with a higher voltage level.

In the period P4, a word line discharge operation may be performed. Specifically, the equalized selected word line SWL, non-selected word lines USWL, and dummy word lines PWL may be discharged. The voltages of each of the selected word line SWL, non-selected word lines USWL, and dummy word lines PWL may be discharged through corresponding global row lines. However, it can take a long time for the high-level pass voltage VP to be discharged, causing residual voltage to remain on the non-selected word lines USWL. As a result, the channel of the selected string may be negatively boosted due to coupling with the voltage reduction of the non-selected word lines USWL in their floated state.

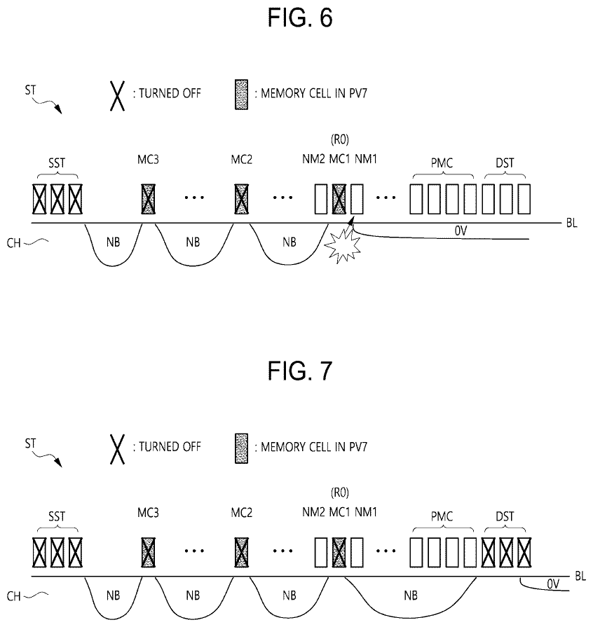

FIG. 6 is a diagram illustrating a situation in which a read disturb occurs during a period of a word line discharge operation in a read operation, according to an embodiment of the present disclosure. The period may correspond to the period P4 in FIG. 5. In FIG. 6 and subsequent figures, the number of source select transistors SST, dummy memory cells PMC, and drain select transistors DST included in the selected string ST may be exemplary.

Referring to FIG. 6, there may be a situation in which one or more of the drain select transistors DST are turned on rather than turned off in the period P4 in which the word line discharge operation of the read operation is performed. Hereinafter, the period P4 may be referred to as ‘word line discharge time.’ Specifically, the drain select transistors DST may be located in a region with fewer ON stacks (Oxide/Nitride stacks) and a higher plug CD (Critical Dimension) than the source select transistors SST. Therefore, the RC delay of the drain select lines DSL coupled to the gate metal of the drain select transistors DST may be significant due to the high surface resistance of the drain select lines DSL. As a result, if the drain select lines DSL are discharged slowly in the period P3 where the equalization operation is performed, such as the situation 41 in FIG. 5, the drain select transistors DST may remain turned on even in the word line discharge time P4. Hereinafter, the period P3 may be referred to as an ‘equalization time.’

And, if a memory cell MC1 that is in a high program state (e.g., program state PV7) is a target memory cell and a read voltage (e.g., read voltage R0) that is significantly lower than the pass voltage VP is applied to the selected word line SWL in the period P2, the target memory cell MC1 may be turned off before a first adjacent memory cell NM1 as the selected word line SWL is discharged. The first adjacent memory cell NM1 may be a memory cell adjacent to the target memory cell MC1 in a direction of the drain select transistors DST in the selected string ST. When the target memory cell MC1 is turned off, memory cells between the target memory cell MC1 and the drain select transistors DST and dummy memory cells PMC may still be turned on. Therefore, a voltage of a bit line BL (e.g., a ground voltage) may be transferred through the turned-on drain select transistors DST to the channel CH of the first adjacent memory cell NM1. Meanwhile, similar to the target memory cell MC1, the memory cells MC2 and MC3 in the program state PV7 may also be turned off.

Accordingly, the channels CH between the source select transistors SST and the respective memory cells MC1 to MC3 may be negatively boosted (illustrated as ‘NB’). In particular, the channel CH of a second adjacent memory cell NM2 adjacent to the target memory cell MC1 in a direction of the source select transistors SST in the selected string ST may also be negatively boosted. As a result, the channel CH of the second adjacent memory cell NM2 is negatively boosted and a ground voltage is transferred to the channel CH of the first adjacent memory cell NM1, which may cause HCI disturb to the first adjacent memory cell NM1.

FIG. 7 is a diagram illustrating an operation for mitigating the effects of a read disturb, according to an embodiment of the present disclosure.

Referring to FIG. 7, the control logic 110 may control the drain select transistors DST to be fully turned off during the word line discharge time P4 of the read operation. Specifically, in the equalization time P3, the voltage generation circuit 120 may generate a negative voltage, and the decoder 130 may transfer the negative voltage to the global drain select lines while coupling the drain select lines DSL to the global drain select lines. Thus, the drain select lines DSL may be discharged more quickly in response to the negative voltage, despite the RC delay, allowing the drain select transistors DST to be completely turned off during the word line discharge time P4. When the drain select transistors DST are turned off, the channels CH between the target memory cell MC1 and the drain select transistors DST may be negatively boosted as previously described. As a result, the ground voltage of the bit line BL may not be transferred to the channel CH of the first adjacent memory cell NM1, thereby preventing the introduction of HCI disturb into the first adjacent memory cell NM1.

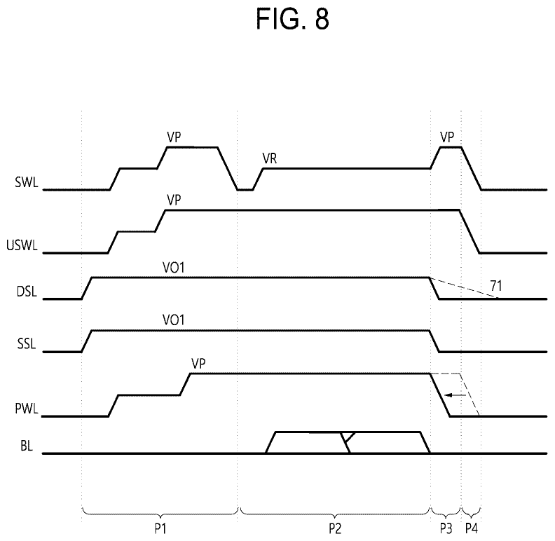

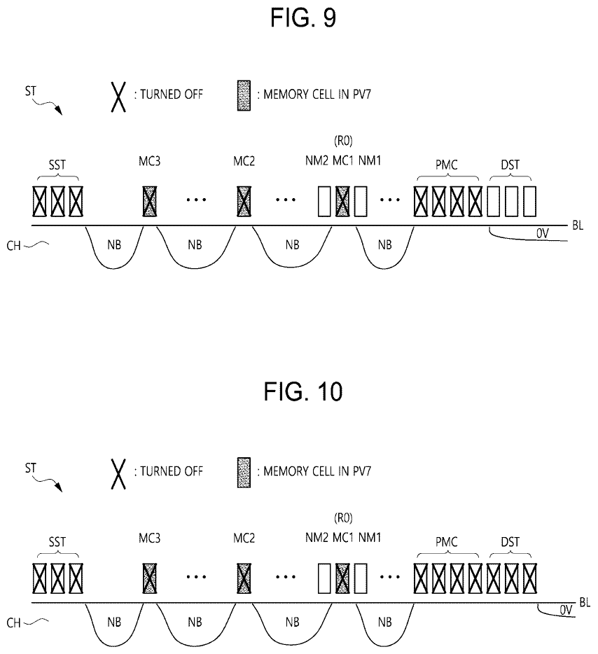

FIG. 8 is a timing diagram illustrating the execution of a read operation on a target memory cell, according to an embodiment of the present disclosure. FIG. 9 is a diagram illustrating an operation for mitigating the effects of a read disturb, according to an embodiment of the present disclosure.

Referring to FIG. 8, the control logic 110 may control dummy word lines PWL to be discharged during the equalization time P3 of the read operation. For example, in the equalization time P3, the dummy word lines PWL may begin to be discharged at the same time as the drain select lines DSL and source select lines SSL.

Also, referring to FIG. 9, the control logic 110 may control the dummy memory cells PMC to be completely turned off during the word line discharge time P4 of the read operation. Specifically, in the equalization time P3, the voltage generation circuit 120 outputs a negative voltage, and the decoder 130 may transfer the negative voltage to the global dummy word lines while coupling the dummy word lines PWL to the global dummy word lines. Thus, the dummy word lines PWL may be quickly discharged, allowing the dummy memory cells PMC to be completely turned off in the discharge time P4. When the dummy memory cells PMC are turned off, the channels CH between the target memory cell MC1 and the dummy memory cells PMC may be negatively boosted. As a result, even if the drain select lines DSL are slowly discharged, as illustrated in a situation 71 in FIG. 8, causing the drain select transistors DST to remain turned on during the discharge time P4, the ground voltage of the bit line BL is not transferred to the channel CH of the first adjacent memory cell NM1, thereby preventing the introduction of HCI disturb into the first adjacent memory cell NM1.

In an embodiment, dummy word lines PWL adjacent to the source select lines SSL in the selected string ST may be controlled in a manner similar to that described with reference to FIGS. 8 and 9 for the dummy word lines PWL adjacent to the drain select lines DSL.

FIG. 10 is a diagram illustrating an operation for mitigating the effects of a read disturb, according to an embodiment of the present disclosure.

Referring to FIG. 10, the operations described with reference to FIG. 7 may be performed in conjunction with the operations described with reference to FIGS. 8 and 9. Specifically, in the equalization time P3, the decoder 130 may transfer a negative voltage output from the voltage generation circuit 120 to the global drain select lines and the global dummy word lines. Thus, the drain select transistors DST and the dummy memory cells PMC may be completely turned off during the word line discharge time P4. Thus, the ground voltage of the bit line BL may not be transferred to the channel CH of the first adjacent memory cell NM1, thereby preventing the introduction of HCI disturb into the first adjacent memory cell NM1.

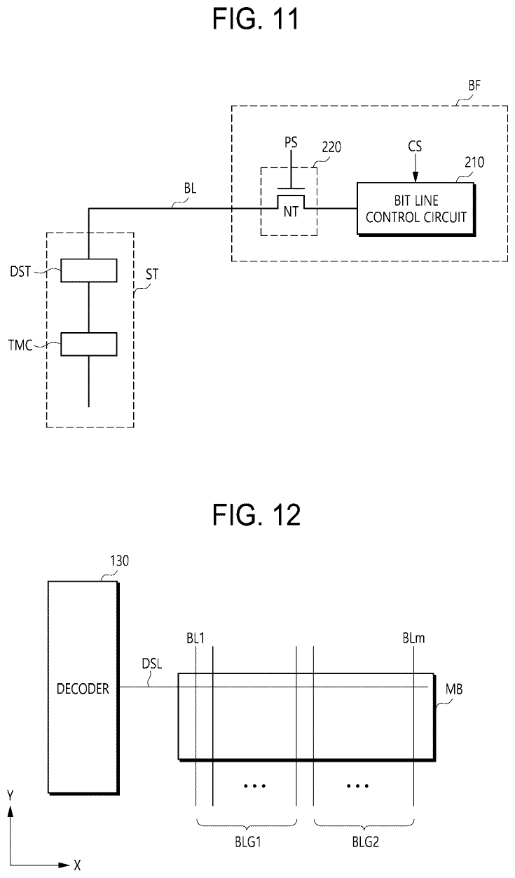

FIG. 11 is a block diagram illustrating a buffer circuit BF according to an embodiment of the present disclosure.

Referring to FIG. 11, the buffer circuit BF may be coupled through a bit line BL to a selected string ST including a target memory cell TMC. The buffer circuit BF may precharge the bit line BL based on a verification result for the target memory cell TMC while a connection signal PS is enabled in a bit line setup operation of a program operation.

The bit line setup operation may involve precharging the bit line BL to a first bit line voltage level if the verification result for the target memory cell TMC indicates program completion. Conversely, if the verification result indicates program incompletion, the bit line BL may be precharged to a second bit line voltage level, which is lower than the first bit line voltage level. Further, in the bit line setup operation, one or more drain select transistors DST included in the selected string ST may be turned on, and the selected string ST may be coupled with the bit line BL. Thus, the channel of the selected string ST may also be boosted to the first bit line voltage level or the second bit line voltage level. When a program voltage is applied to the target memory cell TMC after the bit line setup operation is performed, the target memory cell TMC may be program-inhibited or programmed depending on the voltage level of the channel of the selected string ST. In an embodiment, the first bit line voltage level may be a program-inhibit voltage level, while the second bit line voltage level may be a program-allow voltage level.

The buffer circuit BF may include a bit line control circuit 210 and a connection circuit 220. A control signal CS input to the bit line control circuit 210 and the connection signal PS input to the connection circuit 220 may be included in the data processing circuit control signal DPC of FIG. 1.

The bit line control circuit 210 may store data to be stored in the target memory cell TMC in a program operation. In addition, the bit line control circuit 210 may store a verification result indicating whether the program operation has completed for the target memory cell TMC. The bit line control circuit 210 may output a voltage corresponding to a verification result in a bit line setup operation. The bit line control circuit 210 may operate in response to the control signal CS.

The connection circuit 220 may couple the bit line BL and the bit line control circuit 210 in response to the connection signal PS, such that the bit line BL is precharged based on a voltage output from the bit line control circuit 210 in the bit line setup operation. In an embodiment, the connection circuit 220 may include an NMOS transistor NT. The NMOS transistor NT may include a drain coupled to the bit line control circuit 210, a source coupled to the bit line BL, and a gate to receive the connection signal PS. When the NMOS transistor NT is turned on in response to the connection signal PS being enabled at a predetermined voltage level, a voltage level of the bit line BL may be, for example, a voltage level of the connection signal PS minus a threshold voltage level of the NMOS transistor NT.

In the bit line setup operation, a predetermined turn-on voltage may be applied to one or more of the drain select transistors DST to facilitate channel boosting of the selected string ST. When the drain select transistors DST are turned on in response to the turn-on voltage, the selected string ST may be coupled with the bit line BL. At this time, the RC delay of the drain select lines DSL may be significant due to the high surface resistance of the drain select lines DSL coupled to the gate metal of the drain select transistors DST. If the RC delay is large, the turn-on voltage might not be adequately delivered, preventing the drain select transistors DST from turning on properly. Thus, if the channel of the selected string ST is intended to be boosted to the first bit line voltage level but the drain select transistors DST are not turned on properly, such channel boosting may be insufficient. Furthermore, if the bit line BL is a distant bit line from the decoder 130, the insufficient channel boosting may be further aggravated by the increased RC delay. This can result in program disturb being induced in the selected string ST.

In the bit line setup operation, the control logic 110 may enable the connection signal PS for a first duration if the bit line BL is included in a first bit line group and for a second duration if the bit line BL is included in a second bit line group. The second bit line group may be located farther from the decoder 130 than the first bit line group. The second duration may be longer than the first duration. Thus, even if the RC delay of the drain select lines DSL prevents the drain select transistors DST coupled to the distant bit line BL from turning on properly, the channel coupled to the distant bit line BL may still be sufficiently boosted during the longer second duration. As a result, program disturb can be effectively suppressed.

FIG. 12 is a diagram illustrating a first bit line group BLG1 and a second bit line group BLG2 according to an embodiment of the present disclosure.

Referring to FIG. 12, bit lines BL1 to BLm may extend in the Y direction and may be spaced apart from each other in the X direction. A decoder 130 may be coupled to the same memory block MB as the bit lines BL1 to BLm through one or more drain select lines DSL. The bit lines BL1 to BLm may be grouped into the first bit line group BLG1 and the second bit line group BLG2. The number of bit lines included in the first bit line group BLG1 and the number of bit lines included in the second bit line group BLG2 may be the same or different. The second bit line group BLG2 may be located farther from the decoder 130 than the first bit line group BLG1.

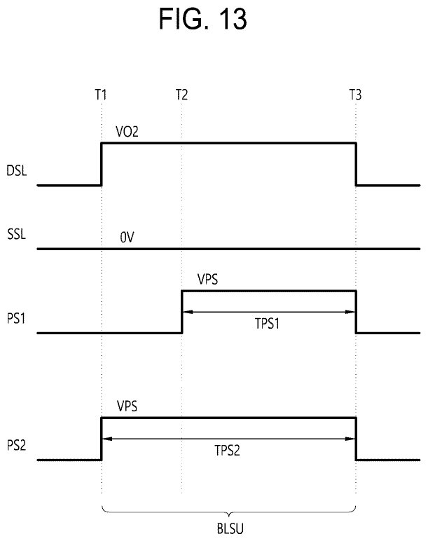

FIG. 13 is a timing diagram illustrating the execution of a bit line setup operation during a bit line setup time BLSU according to an embodiment of the present disclosure. The bit line setup time BLSU may be part of the duration of a program operation.

Referring to FIG. 13, drain select lines DSL may be one or more drain select lines DSL coupled to a selected string ST on which the program operation is to be performed. Source select lines SSL may be one or more source select lines SSL coupled to the selected string ST. A first connection signal PS1 may be a signal applied to the connection circuit 220 of FIG. 11 coupled to a bit line BL of the first bit line group BLG1. A second connection signal PS2 may be a signal applied to the connection circuit 220 coupled to a bit line BL of the second bit line group BLG2.

A predetermined turn-on voltage V02 may be applied to the drain select lines DSL during the bit line setup time BLSU. A ground voltage may be applied to the source select lines SSL during the bit line setup time BLSU. During the bit line setup time BLSU, the first connection signal PS1 may be enabled for a first duration TPS1, and the second connection signal PS2 may be enabled for a second duration TPS2, which is longer than the first duration TPS1. The first connection signal PS1 and the second connection signal PS2 may be enabled with a voltage level VPS.

As shown, the start time T2 of the first duration TPS1 may be later than the start time T1 of the second duration TPS2, while the end time T3 of both the first duration TPS1 and the second duration TPS2 may be the same. In another embodiment, the start time of both the first duration TPS1 and the second duration TPS2 may be the same, while the end time of the first duration TPS1 may precede the end time of the second duration TPS2.

In another embodiment, the bit lines BL1 to BLm may be grouped into a plurality of bit line groups, more than two, with the connection signal PS being enabled for a duration corresponding to each of the plurality of bit line groups. The greater the distance from the decoder 130, the longer the duration of the connection signal PS for the corresponding bit line group.

A person skilled in the art to which the present disclosure pertains can understand that the present disclosure may be carried out in other specific forms without changing its technical spirit or essential features. Therefore, it should be understood that the embodiments described above are illustrative in all aspects, not limitative. The scope of the present disclosure is defined by the claims to be described below rather than the detailed description, and it should be construed that the meaning and scope of the claims and all changes or modified forms derived from the equivalent concept thereof are included in the scope of the present disclosure.

What is claimed is:

1. A memory device, comprising:
a string including at least one drain select transistor coupled to at least one drain select line;
a voltage generation circuit configured to generate at least one operating voltage;
a decoder configured to transfer the at least one operating voltage to at least one global drain select line, and configured to couple the at least one global drain select line with the at least one drain select line; and
a control logic configured to control the voltage generation circuit to generate a negative voltage while an equalization operation is performed, and configured to control the decoder to transfer the negative voltage to the at least one global drain select line while coupling the at least one global drain select line with the at least one drain select line.

2. The memory device of claim 1, wherein the string further comprises a memory cell coupled to a selected word line and at least one memory cell coupled to at least one non-selected word line, and
wherein the control logic is configured to control the voltage generation circuit and the decoder such that a voltage level of the selected word line and a voltage level of the at least one non-selected word line are equalized while the equalization operation is performed.

3. The memory device of claim 2, wherein the control logic is configured to control the voltage generation circuit and the decoder such that the selected word line and the at least one non-selected word line are discharged after the equalization operation.

4. The memory device of claim 1, wherein the at least one drain select line is discharged in response to the negative voltage, and the at least one drain select transistor is turned off in response to the discharge of the at least one drain select line.

5. The memory device of claim 1, wherein the string further comprises at least one source select transistor coupled to at least one source select line, and
wherein the control logic is configured to control the voltage generation circuit and the decoder such that the at least one source select line is discharged while the equalization operation is performed.

6. A memory device, comprising:
a string including at least one dummy memory cell coupled to at least one dummy word line;
a voltage generation circuit configured to generate at least one operating voltage;
a decoder configured to transfer the at least one operating voltage to at least one global dummy word line, and configured to couple the at least one global dummy word line with the at least one dummy word line; and
a control logic configured to control the voltage generation circuit to generate a negative voltage while an equalization operation is performed, and configured to control the decoder to transfer the negative voltage to the at least one global dummy word line while coupling the at least one global dummy word line with the at least one dummy word line.

7. The memory device of claim 6, wherein the string further comprises a memory cell coupled to a selected word line and at least one memory cell coupled to at least one non-selected word line, and
wherein the control logic is configured to control the voltage generation circuit and the decoder such that a voltage level of the selected word line and a voltage level of the at least one non-selected word line are equalized while the equalization operation is performed.

8. The memory device of claim 7, wherein the control logic is configured to control the voltage generation circuit and the decoder such that the selected word line and the at least one non-selected word line are discharged after the equalization operation.

9. The memory device of claim 6, wherein the at least one dummy word line is discharged in response to the negative voltage, and the at least one dummy memory cell is turned off in response to the discharge of the at least one dummy word line.

10. The memory device of claim 6, wherein the string further comprises at least one drain select transistor coupled to at least one drain select line and at least one source select transistor coupled to at least one source select line, and
wherein the control logic is configured to control the voltage generation circuit and the decoder such that the at least one drain select line and the at least one source select line are discharged while the equalization operation is performed.

11. The memory device of claim 10, wherein the control logic is configured to control the decoder to transfer the negative voltage to at least one global drain select line while coupling the at least one global drain select line with the at least one drain select line.

12. The memory device of claim 11, wherein the at least one drain select line is discharged in response to the negative voltage, and the at least one drain select transistor is turned off in response to the discharge of the at least one drain select line.

13. A memory device, comprising:
a string coupled to a bit line and including a target memory cell;
a buffer circuit configured to precharge the bit line based on a verification result for the target memory cell while a connection signal is enabled in a bit line setup operation; and
a control logic configured to enable the connection signal for a first duration when the bit line is included in a first bit line group, and configured to enable the connection signal for a second duration when the bit line is included in a second bit line group, in the bit line setup operation.

14. The memory device of claim 13, further comprising a decoder coupled to the string through a plurality of row lines,
wherein the second bit line group is located farther from the decoder than the first bit line group, and the second duration is longer than the first duration.

15. The memory device of claim 13, wherein the buffer circuit is configured to precharge the bit line to a first voltage level when the verification result indicates program completion, and configured to precharge the bit line to a second voltage level lower than the first voltage level when the verification result indicates program incompletion.

16. The memory device of claim 13, wherein the buffer circuit comprises:
a bit line control circuit configured to store the verification result, and configured to output a voltage corresponding to the verification result in the bit line setup operation; and
a connection circuit configured to couple the bit line control circuit with the bit line in response to the connection signal, such that the bit line is precharged based on the voltage output from the bit line control circuit.
